(19) United States
(12) Patent Application Publication
(10) Pub. No.: US 2025/0160171 A1
(43) Pub. Date: May 15, 2025

(54) DISPLAY DEVICE AND METHOD OF MANUFACTURING THE SAME

(71) Applicant: Samsung Display Co., Ltd., Yongin-Si (KR)

(72) Inventors: Myung Hwan KIM, Yongin-si (KR); Se Joong SHIN, Yongin-si (KR)

(21) Appl. No.: 18/754,150

(22) Filed: Jun. 26, 2024

(30) Foreign Application Priority Data
Nov. 13, 2023 (KR) 10-2023-0156817

(51) Int. Cl. H10K 59/80; H05K 1/18; H10K 102/00

(52) U.S. Cl. CPC H10K 59/8722; H05K 1/189; H10K 59/8794; H05K 2201/10128; H10K 2102/311

(57) ABSTRACT

Provided are a display device and a method of manufacturing the same. A display device comprises a display panel comprising a first area comprising a display area, a second area spaced apart from the first area, and a bendable third area between the first area and the second area. A bonding layer is in the first area, the second area, and the third area and located on a lower surface of the display panel. A panel bottom cover is in the first area and bonded to the bonding layer, and a support film is in the second area and bonded to the bonding layer. A gap separating the panel bottom cover and the support film from each other is in the third area.

This application claims the benefit of Korean Patent Application No. 10-2023-0156817, filed on Nov. 13, 2023, in the Korean Intellectual Property Office, the disclosure of which is incorporated herein in its entirety by reference.

### BACKGROUND

### 1. Field

The present disclosure relates to a display device and a method of manufacturing the same.

### 2. Description of the Related Art

The development of our information society develops has increased demand for display devices capable of displaying images and information in various forms. For example, display devices are applied to electronic devices such as smartphones, digital cameras, notebook computers, navigation devices, and smart televisions,

Various types of display devices such as liquid crystal displays (LCDs) and organic light emitting displays (OLEDs) are currently in use. OLEDs display images using organic light emitting elements that generate light through recombination of electrons and holes. An OLED may include a plurality of transistors that provide a driving current to an organic light emitting element.

Recent attempts have been made to minimize the thickness of display devices to make them lighter.

### SUMMARY

Aspects of the present disclosure may provide a display device having reduced thickness and manufacturing costs and may provide a method of manufacturing the display device. However, aspects of the present disclosure are not restricted to those set forth herein. The above and other aspects of the present disclosure will become more apparent in view of the detailed description of the present disclosure given below.

According to an aspect of the present disclosure, a display device may comprise: a display panel comprising a first area comprising a display area, a second area spaced apart from the first area, and a bendable third area located between the first area and the second area, a bonding layer disposed in the first area, the second area and the third area of the display panel and located on a lower surface of the display panel, a panel bottom cover disposed in the first area of the display panel and bonded to the bonding layer, and a support film disposed in the second area of the display panel and bonded to the bonding layer, wherein a gap which separates the panel bottom cover and the support film from each other is provided in the third area.

In an embodiment, the bonding layer may comprise a fixed adhesive layer located on the lower surface of the display panel and a light-peelable adhesive layer located on a lower surface of the fixed adhesive layer.

In an embodiment, the bonding layer may comprise an optical coupling adhesive layer located on the lower surface of the display panel and a light-peelable adhesive layer located on a lower surface of the optical coupling adhesive layer.

In an embodiment, the adhesive strength of the optical coupling adhesive layer after light irradiation may be 250 gf/inch or more, and the adhesive strength of the light-peelable adhesive layer after the light irradiation is 50 gf/inch or less.

In an embodiment, the display device may further include a protective layer formed on a lower surface of the light-peelable adhesive layer in the third area.

In an embodiment, the panel bottom cover may comprise: an adhesive member bonded to the bonding layer in the first area, a heat dissipation member bonded to the adhesive member and dissipating heat of the display panel, and a bending adhesive member bonded to the heat dissipation member and fixing a bent configuration of the display panel when the display panel is bent.

In an embodiment, the support film may further include a burr pattern protruding downward from a lower surface of the support film along an inner surface around the gap.

In an embodiment, an angle formed by the inner surface of the support film adjacent to the third area and a lower surface of the bonding layer may be 70 degrees or less.

In an embodiment, the display device may further include a driving chip disposed in the second area of the display panel and located on an upper surface facing the lower surface of the display panel.

In an embodiment, the display device may further include a flexible printed circuit board electrically connected to the driving chip of the second area, and a substrate cover layer formed on a lower surface of the flexible printed circuit board.

In an embodiment, an end of the flexible printed circuit board may be bonded to an edge of the display panel in the second area, and the substrate cover layer is located on the lower surface of the flexible printed circuit board at the edge of the display panel and contacts a side surface of the display panel, a side surface of the bonding layer and a side surface of the support film in the second area.

In an embodiment, the substrate cover layer may further include a cover portion extending from a lower surface of the substrate cover layer toward the side surface of the support film which contacts the substrate cover layer and covering a portion of a lower area of the support film.

According to another aspect of the present disclosure, there is provided a display device comprising: a display panel comprising a first area comprising a display area, a second area spaced apart from the first area, and a bendable third area located between the first area and the second area, a bonding layer disposed in the first area, the second area and the third area of the display panel and located on a lower surface of the display panel; a support film disposed in the second area of the display panel and bonded to the bonding layer; a flexible printed circuit board having an end bonded to a distal area of the display panel in the second area, and a substrate cover layer formed on a lower surface of the flexible printed circuit board.

In an embodiment, the bonding layer may comprise a first adhesive layer located on the lower surface of the display panel and a second adhesive layer located on a lower surface of the first adhesive layer, and the second adhesive layer is a light-peelable adhesive layer.

In an embodiment, the display device may further include a protective layer formed on a lower surface of the light-peelable adhesive layer in the third area.

In an embodiment, the substrate cover layer may further include a cover portion extending from a lower surface of the substrate cover layer toward a side surface of the support film which contacts the substrate cover layer and covering a portion of a lower area of the support film.

In an embodiment, the display device may further include a panel bottom cover disposed in the first area of the display panel and bonded to the bonding layer.

In an embodiment, the panel bottom cover may comprise an adhesive member bonded to the bonding layer in the first area, a heat dissipation member bonded to the adhesive member and dissipating heat of the display panel, and a bending adhesive member bonded to the heat dissipation member and fixing a bent configuration of the display panel when the display panel is bent, the third area comprises a gap which is a space formed between the support film and the heat dissipation member, and the support film further comprises a burr pattern protruding downward from the lower surface of the support film along an inner surface around the gap.

In an embodiment, the display device may further include a driving chip disposed in the second area of the display panel and located on an upper surface of the display panel.

According to another aspect of the present disclosure, there is provided a method of manufacturing a display device having a display panel which comprises a first area comprising a display area, a second area spaced apart from the first area, and a bendable third area comprising a gap between the first area and the second area, the method comprising: preparing the display panel which comprises a bonding layer formed on the entire lower surface of the display panel in the first through third areas and a support film layer bonded to the bonding layer, forming a cutting line in the support film layer as a boundary between the second area and the third area, selectively irradiating light to the first and third areas of the support film layer in which the cutting line is formed, forming the support film layer into a support film in the second area by peeling and removing the support film layer of the first and third areas irradiated with the light, and forming a panel bottom cover on the bonding layer of the first area at a position spaced apart from the support film of the second area with the gap interposed therebetween.

In an embodiment, the bonding layer may comprise a first adhesive layer located on the lower surface of the display panel and a second adhesive layer located on a lower surface of the first adhesive layer, and the second adhesive layer is a light-peelable second adhesive layer.

In an embodiment, the first adhesive layer may be a fixed adhesive layer whose adhesive strength is maintained without being changed by light irradiation or an optical coupling adhesive layer. The optical coupling adhesive layer may have an adhesive strength of 100 gf/inch or less before light irradiation and may increase the adhesive strength to 250 gf/inch or more after light irradiation.

In an embodiment, the second adhesive layer may be formed as a light-peelable second adhesive layer having an adhesive strength of 250 gf/inch or more before light irradiation, and an adhesive strength is reduced to 50 gf/inch or less after light irradiation.

In an embodiment, the cutting line may be formed by cutting the support film layer through laser processing.

In an embodiment, in the step of forming the cutting line, a burr pattern protruding from the support film may be formed in the cutting area where the cutting line is formed.

In an embodiment, in the step of forming the cutting line, a cut surface is formed in the support film layer, and an inclination angle formed between the cut surface and the lower surface of the second adhesive layer may be 70 degrees or less.

In an embodiment, in the step of irradiating the light, a mask including a light transmitting portion corresponding to the first and third areas and a light blocking portion corresponding to the second area may be disposed based on the cutting line.

In an embodiment, forming the panel bottom cover includes forming an adhesive member on the second adhesive layer of the bonding layer in the first area, and forming a heat dissipation member that is coupled to the adhesive member to radiate heat from the display panel, and forming a bending adhesive member coupled to the heat dissipation member to fix the bent configuration of the display panel when it is bent.

In an embodiment, in the third area, the method may further include forming a protective layer on at least one of the upper surface of the display panel and the lower surface of the light-peelable second adhesive layer.

In an embodiment, the method may further include forming a driving chip disposed in the second area of the display panel and located on an upper surface of the display panel.

In an embodiment, the method may further include forming a flexible printed circuit board electrically connected to the driving chip and having an one end coupled to a distal area of the display panel in the second area, and forming a substrate cover layer located on the lower surface of the flexible printed circuit board in the end region of the display panel and contacting the side of the display panel, the side of the bonding layer, and the side of the support film in the second area.

In an embodiment, in the step of forming the substrate cover layer, the substrate cover layer may be formed with a cover portion extending from a lower surface of the substrate cover layer toward a side of the support film in contact with one side of the substrate cover layer and covering a portion of a lower region of the support film.

According to the present disclosure, a bonding layer may be formed on the entire lower surface of a display panel. Therefore, a panel bottom cover, a support film, and a lower protective layer in different areas can all be bonded to the lower surface of the display panel using one bonding layer. That is, since only one bonding layer is provided, the number of components for bonding the above elements can be reduced, thereby reducing thickness and manufacturing costs. In addition, since the process of bonding each of the above elements is simplified, the efficiency of a manufacturing process can be improved.

In addition, in the manufacturing process, a support film layer may be bonded and then peeled off by a light-peelable adhesive layer whose adhesive strength is reduced by light irradiation. Therefore, the support film layer does not remain to cause defects or damage a peeled surface. Accordingly, a defect rate can be reduced, and issues such as tearing during a peeling process can be suppressed.

Meanwhile, if the support film is disposed in a first area, the position of a neutral plane may be changed by the support film when the display panel is bent or folded. However, in the present disclosure, since the support film is not disposed in the first area, the position of the neutral plane can be kept unchanged.

In addition, if the support film is located in the first area, the overall thickness may increase because stacked structures increase in the first area which is a display area. However, according to the present disclosure, the support film is disposed in a second area which is a non-display area and is not disposed in the first area which is the display area. Therefore, the stacked structures can be reduced in the first area which is the display area, thereby reducing the overall thickness of a display device.

In addition, since the support film is not disposed in the first area, the stacked structures can be reduced in the first area which is the display area, thereby reducing manufacturing costs.

In addition, the support film is not disposed in the first area but is disposed on the lower surface of the display panel at a position corresponding to a driving chip of the second area. Therefore, the display panel can be protected in the second area, and the problems of cracks and driving chip defects can be solved.

In addition, since the panel bottom cover is located in the first area, the display panel can be stably supported in the second area.

In addition, a cover portion is formed adjacent to the support film of the second area to seal a portion of a lower surface of the support film. Therefore, it is possible to prevent the penetration of moisture into a flexible printed circuit board and the driving chip connected to the flexible printed circuit board, thereby preventing corrosion due to the moisture.

However, the effects of the present disclosure are not limited to the aforementioned effects, and various other effects are included in the present disclosure.

### BRIEF DESCRIPTION OF THE DRAWINGS

These and/or other aspects will become apparent and more readily appreciated from the following description of example embodiments, taken in conjunction with the accompanying drawings.

FIG. 1 is a perspective view of a display device according to an embodiment.

FIG. 2 is a plan view of the display device of FIG. 1.

FIG. 3 is a rear view of the display device of FIG. 1.

FIG. 4 is a rear view of a display panel in the display device of FIG. 3;

FIG. 5 is a cross-sectional view schematically illustrating a stacked structure in an embodiment of a display panel.

FIG. 6 is an enlarged cross-sectional view of the stacked structure of the display panel of FIG. 5.

FIG. 7 is a cross-sectional view taken along line X1-X1′ of FIGS. 2 and 3.

FIG. 8 is an enlarged view of a first area of FIG. 7.

FIG. 9 is an enlarged view of a boundary area between a second area and a third area of FIG. 7.

FIG. 10 is an enlarged view of the display panel, a bonding layer, a support film, and a panel bottom cover in the first through third areas of FIG. 7.

FIG. 11 is an enlarged view of a portion of FIG. 7 showing the second area and a flexible printed circuit board bonding area.

FIG. 12 is a cross-sectional view of the display device of FIG. 7 in a bent state.

FIG. 13 is a flowchart for a method of manufacturing a display device according to an embodiment of the present disclosure.

FIG. 14 is a perspective view of an embodiment of a mother substrate for a display device.

FIG. 15 is a rear view of the mother substrate illustrated in FIG. 14.

FIGS. 16, 17, 18, 19, 20, and 21 are cross-sectional views of structures formed during the manufacturing process of FIG. 13.

### DETAILED DESCRIPTION

Example embodiments will now be described more fully hereinafter with reference to the accompanying drawings. The example embodiments illustrate principles and aspects of the current disclosure, but this disclosure should not be construed as limited to the specific embodiments set forth herein. Rather, the example embodiments are described, so that this disclosure will be thorough and complete and will be understood by those skilled in the art.

The same reference numbers indicate the same components throughout the specification and drawings. In the drawings, the thicknesses of layers and regions and the sizes or shapes of elements may be exaggerated or altered for clarity or ease of illustration.

When this disclosure refers to a layer as being “on” another layer or substrate, the layer can be directly on the other layer or substrate, or intervening layers may also be present. Likewise, elements referred to as “below”, “left”, or “right” of other elements include cases where the elements are directly adjacent to the other elements or cases where a layer or other material is interposed between the elements.

Although the terms “first,” “second,” etc. may be used herein to describe various elements, the elements are not limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Hereinafter, embodiments of the present disclosure will be described with reference to the accompanying drawings.

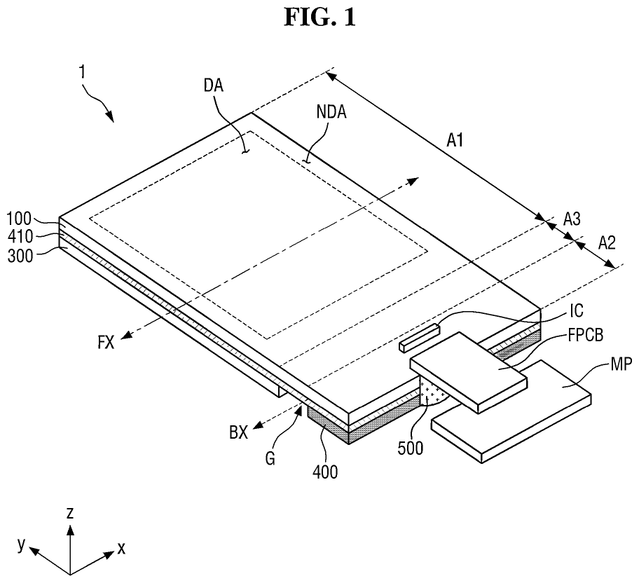

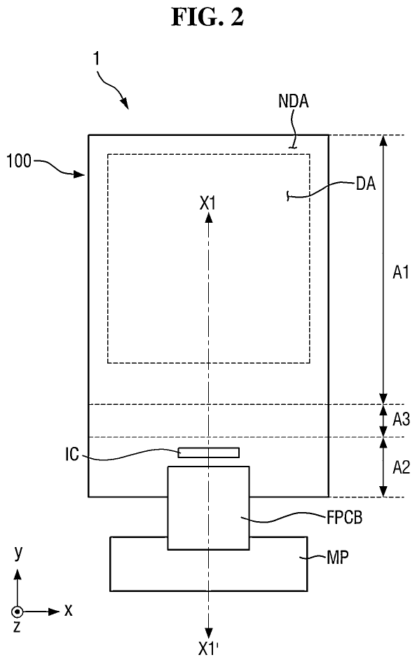

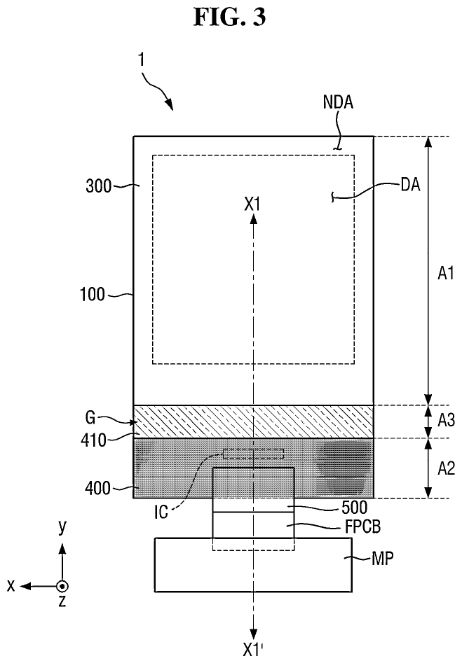

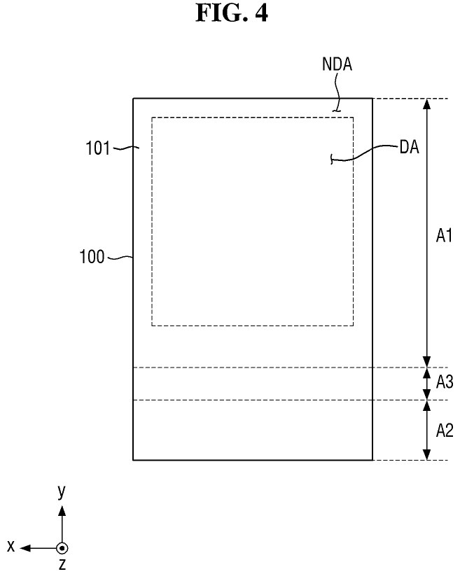

FIG. 1 is a perspective view of a display device 1 according to an embodiment. FIG. 2 is a plan view of the display device 1 illustrated in FIG. 1. FIG. 3 is a rear view of the display device 1 illustrated in FIG. 1. FIG. 4 is a rear view of a display panel 100 in the display device 1 of FIG. 3. Here, FIGS. 1 through 4 illustrate the display device 1 before being bent or folded.

The display device 1 may be applied to a portable terminal or the like. Examples of the portable terminal may include tablet PCs, smartphones, personal digital assistants (PDAs), portable multimedia players (PMPs), game consoles, and wristwatch-type electronic devices. However, the present disclosure is not limited to the specific type of display device 1. For example, in other embodiments of the present disclosure, the display device 1 may be used in small and medium-sized electronic equipment such as PCs, notebook computers, car navigation devices and cameras as well as in large-sized electronic equipment such as televisions and outdoor billboards.

In an embodiment, the display panel 100 in the display device 1 may have a rectangular shape. The display panel 100 may have a rectangular shape in plan view, and the display panel 100 may include both short sides, both long sides, and a rectangular panel surface formed by the short sides and the long sides.

The display panel 100 is illustrated as a rectangular planar shape in which each corner where a long side and a short side meet is right-angled. However, the present disclosure is not limited thereto. The corners of the display panel 100 may alternatively be curved, and the planar shape of the display panel 100 may alternatively be circular or may have various other shapes.

In FIG. 1, the short sides of the display panel 100 extend in a first direction x, the long sides of the display panel 100 extend in a second direction y, and a direction perpendicular to the panel surface of the display panel 100 is described herein as a third direction z. In addition, unless otherwise defined below, in the present specification, “above”, “top”, “upper surface”, and “upper side” of the display panel 100 refer to a direction in which an arrow of the third direction z points, and “below”, “bottom”, “lower surface”, and “lower side” of the display panel 100 refer to a direction opposite to the direction in which the arrow of the third direction z points.

The display panel 100 may include a self-light emitting element. In an exemplary embodiment, the self-light emitting element may include at least one of an organic light emitting diode, a quantum dot light emitting diode, an inorganic material-based micro light emitting diode (e.g., micro LED), and an inorganic material-based nano light emitting diode (e.g., nano LED). For ease of description, each element of the display panel 100 will be described in detail below using an example that includes a self-light emitting element that is an organic light emitting element.

The display panel 100 may be divided or partitioned based on image display functionality, in which case, the display panel 100 may include a display area DA which displays an image and a non-display area NDA which does not display an image. The non-display area NDA may be located around the display area DA and may surround the display area DA.

The display panel 100 may alternatively be divided or partitioned based on bendability, in which case, the display panel 100 may include a first area A1, a second area A2, and a third area A3.

The first area A1 may be spaced apart from the second area A2, may include the display area DA, and may be foldable. For example, an end of the first area A1 can be folded upward or downward based about a folding axis FX extending along the first direction x. That is, if explained based on FIG. 1, the first area A1 can be folded by moving an end of area A1 in the direction in which the arrow of the third direction z points, that is, the upward direction or in the direction opposite to the direction in which the arrow of the third direction z points, that is, the downward direction.

The second area A2 may be spaced apart from the first area A1 and may be a part of the non-display area NDA. The third area A3 may include a gap G located between the first area A1 and the second area A2 and may be another part of the non-display area NDA. The gap G may be formed to cross the non-display area NDA along the first direction x, which is a short-side direction of the display panel 100.

The display panel 100 can be bent based on a bending axis BX extending along the first direction x in the third area A3, and parts of the display panel 100 can be bent downward based on the bending axis BX in the third area A3. As a part of the non-display area NDA of the display panel 100 is bent toward the bottom of the display panel 100, the portion of the non-display area NDA that is visible from above the display device 1 can be reduced, and a bezel width of the display device 1 can be reduced.

A driving chip IC may be disposed on the display panel 100 in the second area A2, and pads connected to the driving chip IC may be disposed in the second area A2.

The driving chip IC may include at least one driving device such as a data driver which transmits data signals to data lines, a gate driver which transmits gate signals to gate lines, and a signal controller which controls the operations of the data driver and the gate driver. The display device 1 may include any number of driving chips and is not limited to a single driving chip IC as shown in the illustrated example.

The driving chip IC may be mounted on the display panel 100 using a chip on plastic method. The driving chip IC may be mounted on the display panel 100 using a pressurizing device. The driving chip IC may be mounted on the display panel 100 using an anisotropic conductive film. Alternatively, in an embodiment, the driving chip IC may be mounted on the display panel 100 using an ultrasonic bonding method without a separate anisotropic conductive film.

Ultrasonic bonding is a method of joining two metals by applying pressure and ultrasonic vibration. When the driving chip IC is mounted on the display panel 100 using the ultrasonic bonding method, a process of applying pressure and ultrasonic vibration to the driving chip IC may be performed. However, the present disclosure is not limited to the above-described embodiment. In an embodiment, the driving chip IC may be mounted on a flexible printed circuit board FPCB in the form of a chip on film.

An end of the flexible printed circuit board FPCB may attach to the second area A2 of the display panel 100 and extend from an edge of the second area A2.

An anisotropic conductive film or the like may connect the flexible printed circuit board FPCB to the pads provided on the display panel 100. The process of connecting the flexible printed circuit board FPCB to the display panel 100 may include a process of applying pressure to the flexible printed circuit board FPCB.

A main circuit board MP may be electrically connected to the display panel 100 through the flexible printed circuit board FPCB and may exchange signals with the driving chip IC. The main circuit board MP may provide image data, control signals, power supply voltages, etc. to the display panel 100 or the flexible printed circuit board FPCB. The main circuit board MP may include active and passive elements.

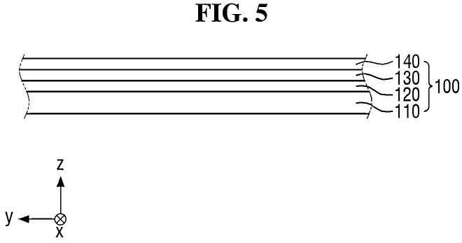

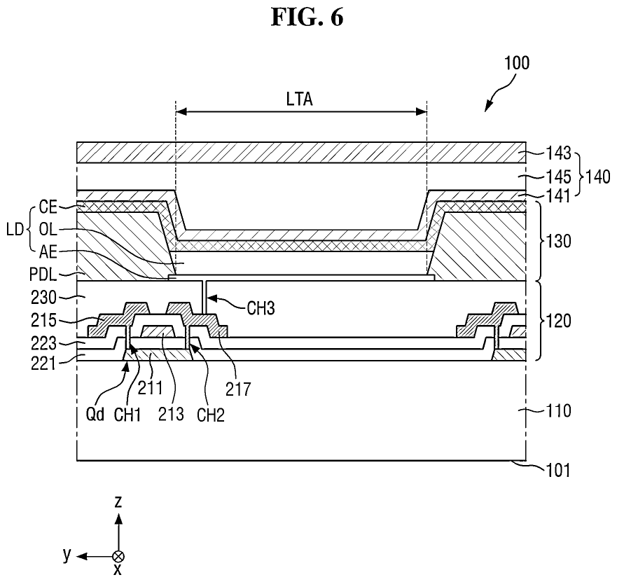

FIG. 5 is a cross-sectional view schematically illustrating a stacked structure of the display panel 100. FIG. 6 is an enlarged cross-sectional view of the stacked structure of the display panel 100 of FIG. 5.

The display panel 100 may include a base substrate 110, a driving layer 120, an organic light emitting element layer 130, and an encapsulation layer 140.

The base substrate 110 provides a lower surface 101 of the display panel 100. The base substrate 110 may be a flexible substrate and may be made of a flexible polymer material. For example, the base substrate 110 may be made of plastic with excellent heat resistance and durability, such as polyethylene ether phthalate, polyethylene naphthalate, polycarbonate, polyarylate, polyetherimide, polyethersulfone, or polyimide. A case where the base substrate 110 includes polyimide is described below as an example.

The driving layer 120 includes elements for providing signals to the organic light emitting element layer 130. The driving layer 120 may include various signal lines, for example, scan lines (not illustrated), data lines (not illustrated), power lines (not illustrated), and emission lines (not illustrated). The driving layer 120 may include a plurality of transistors and capacitors. The transistors may include a switching transistor (not illustrated) and a driving transistor Qd provided in each pixel (not illustrated).

In FIG. 6, the driving transistor Qd formed in the driving layer 120 is illustrated as an example. The driving transistor Qd includes an active layer 211, a gate electrode 213, a source electrode 215, and a drain electrode 217.

The active layer 211 may be disposed on the base substrate 110. The active layer 211 may include polycrystalline silicon. Alternatively, the active layer 211 may include monocrystalline silicon, low-temperature polycrystalline silicon, or amorphous silicon. However, the present disclosure is not limited thereto, and the active layer 211 may include an oxide semiconductor.

The driving layer 120 may further include a first insulating layer 221 disposed on the active layer 211, and the gate electrode 213 may be on the first insulating layer 221.

The first insulating layer 221 may insulate the active layer 211 and the gate electrode 213 from each other. The first insulating layer 221 may include an inorganic insulating material such as silicon oxide, silicon nitride, or silicon oxynitride. The first insulating layer 221 may be a single layer or a multilayer composed of stacked layers of different materials.

The gate electrode 213 may be located on the first insulating layer 221 and may overlap the active layer 211. The gate electrode 213 may include gold (Au), silver (Ag), copper (Cu), nickel (Ni), platinum (Pt), palladium (Pd), aluminum (Al), or molybdenum (Mo).

The driving layer 120 may further include a second insulating layer 223 on the gate electrode 213, and the source electrode 215 and the drain electrode 217 may be disposed on the second insulating layer 223. The second insulating layer 223 may include at least any one of the insulating materials described above for the first insulating layer 221.

The source electrode 215 and the drain electrode 217 may be respectively connected to the active layer 211 through contact holes CHI and CH2 extending through the first insulating layer 221 and the second insulating layer 223. The source electrode 215 and the drain electrode 217 may have, but are not limited to, a metal multilayer structure of titanium (Ti)/aluminum (Al)/titanium (Ti).

The driving layer 120 may further include a protective layer 230 disposed on the source electrode 215 and the drain electrode 217. In some embodiments, the protective layer 230 may be a planarization layer. For example, the protective layer 230 may include an organic insulating material or an inorganic insulating material or may be implemented as a composite of an organic insulating material and an inorganic insulating material.

Although the structure of a switching transistor is not illustrated in FIG. 6, the switching transistors (not illustrated) and the driving transistor Qd may have substantially the same structure or similar structures. However, the present disclosure is not limited thereto, and the switching transistors (not illustrated) and the driving transistor Qd may have different structures. For example, an active layer (not illustrated) of a switching transistor (not illustrated) and the active layer 211 of the driving transistor Qd may be made of different materials or may be disposed on different layers within the display panel 100.

The driving layer 120 may be located in the display area DA and also in the non-display area NDA of the display panel 100. A portion of the driving layer 120 which is located in the non-display area NDA, for example, a portion located in the non-display area NDA of the first area A1, in the second area A2, and in the third area A3 may include wirings and a pad unit electrically connected to the driving chip IC and may further include wirings and a pad unit electrically connected to the flexible printed circuit board FPCB.

The organic light emitting element layer 130 may include an organic light emitting element LD as a self-light emitting element. The organic light emitting element LD may be provided as a top emission type and may emit light in a thickness direction of the display panel 100, which is the third direction z.

The organic light emitting element LD may include a first electrode AE, an organic layer OL, and a second electrode CE.

The first electrode AE may be disposed on the protective layer 230. The first electrode AE may be connected to the drain electrode 217 through a contact hole CH3, which extends through the protective layer 230. The first electrode AE may be a pixel electrode or an anode. The first electrode AE may be a transflective electrode or a reflective electrode. When the organic light emitting element LD is a top emission type, the first electrode AE may be a reflective electrode. The first electrode AE may include any one or more of silver (Ag), magnesium (Mg), aluminum (Al), platinum (Pt), palladium (Pd), gold (Au), nickel (Ni), neodymium (Nd), iridium (Ir) and chromium (Cr), or an alloy thereof.

The first electrode AE may be a single layer made of metal oxide or metal or a multilayer structure having multiple layers. For example, the first electrode AE may have, but is not limited to, a single layer structure of indium tin oxide (ITO), silver (Ag) or a metal mixture (e.g., a mixture of Ag and Mg), a two-layer structure of indium tin oxide (ITO)/magnesium (Mg) or indium tin oxide (ITO)/magnesium fluoride (MgF), or a three-layer structure of indium tin oxide (ITO)/silver (Ag)/indium tin oxide (ITO).

The organic layer OL may include an organic emission layer (EML) made of a low-molecular organic material or a high-molecular organic material. The organic emission layer may emit light in response to an electrical current flowing through the organic emission layer. The organic layer OL may optionally include a hole transport layer (HTL), a hole injection layer (HIL), an electron transport layer (ETL), and an electron injection layer (EIL), in addition to the organic emission layer.

Holes and electrons from the first electrode AE and the second electrode CE, respectively, may be injected into the organic emission layer inside the organic layer OL. The holes and the electrons are combined in the organic emission layer to form excitons, and light is emitted as the excitons fall from an excited state to a ground state.

The second electrode CE may be on the organic layer OL. The second electrode CE may be a common electrode or a cathode. The second electrode CE may be a transmissive electrode or a transflective electrode. When the second electrode CE is a transflective electrode, the second electrode CE may include lithium (Li), lithium fluoride (LiF), calcium (Ca), lithium fluoride (LiF)/calcium (Ca), lithium fluoride (LiF)/aluminum (Al), aluminum (Al), magnesium (Mg), barium fluoride (BaF), barium (Ba), silver (Ag), or a compound or mixture thereof (e.g., a mixture of Ag and Mg). When the second electrode CE is a transmissive electrode, the second electrode CE may include a transparent metal oxide such as indium tin oxide (ITO), indium zinc oxide (IZO), zinc oxide (ZnO) or indium tin zinc oxide (ITZO) or may include molybdenum (Mo), titanium (Ti) or silver (Ag).

The organic light emitting element layer 130 may further include a pixel defining layer PDL disposed on the protective layer 230. The pixel defining layer PDL may be formed with an opening exposing the first electrode AE, and the opening may define an emission area LTA in plan view.

The encapsulation layer 140 may be disposed on the organic light emitting element layer 130. The encapsulation layer 140 may protect the organic light emitting element layer 130 by blocking permeation of external moisture and oxygen.

The encapsulation layer 140 may be formed as thin-film encapsulation and may include one or more organic layers and one or more inorganic layers. For example, the encapsulation layer 140 may include a first inorganic layer 141 on the second electrode CE, an organic layer 145 on the first inorganic layer 141, and a second inorganic layer 143 on the organic layer 145.

The first inorganic layer 141 may also be disposed on the organic light emitting element LD and may prevent the penetration of moisture, oxygen, etc. into the organic light emitting element LD. In some embodiments, the first inorganic layer 141 may include an inorganic material, and the inorganic material may include, for example, any one or more of silicon oxide (SiOₓ), silicon nitride (SiNₓ), and silicon oxynitride (SiONₓ).

The organic layer 145 may be on the first inorganic layer 141. The organic layer 145 may have an upper surface with improved flatness compared to the underlying structure. The organic layer 145 may include an organic material, and the organic material may include, for example, any one of epoxy, acrylate, and urethane acrylate.

The second inorganic layer 143 may be on the organic layer 145. The second inorganic layer 143 may perform substantially the same or similar role as the first inorganic layer 141 and may be made of substantially the same or similar material as the first inorganic layer 141. The second inorganic layer 143 may completely cover the organic layer 145. In some embodiments, the second inorganic layer 143 and the first inorganic layer 141 may contact each other outside the display area DA to form an inorganic-inorganic bond. When the inorganic-inorganic bond is formed, it is possible to effectively prevent the introduction of moisture into the display device 1 from the outside of the display device 1.

Although each of the first inorganic layer 141, the organic layer 145, and the second inorganic layer 143 is illustrated as a single layer in FIG. 6, the present disclosure is not limited thereto. That is, at least one of the first inorganic layer 141, the organic layer 145, and the second inorganic layer 143 may also be formed in a multilayer structure.

The encapsulation layer 140 may not completely cover the non-display area NDA of the display panel 100. For example, the encapsulation layer 140 may not be located in a part of the first area A1 of the display panel 100 between the third area A3 and the display area DA and may not be located in the second area A2 and the third area A3. Alternatively, the encapsulation layer 140 may be located in a part of the first area A1 of the display panel 100 between the third area A3 and the display area DA and may not be located in the second area A2 and the third area A3. For ease of description, a case where the encapsulation layer 140 is located in the display area DA of the display panel 100 and is not located in a part of the first area A1 between the third area A3 and the display area DA and not located in the second area A2 and the third area A3 will be described as an example.

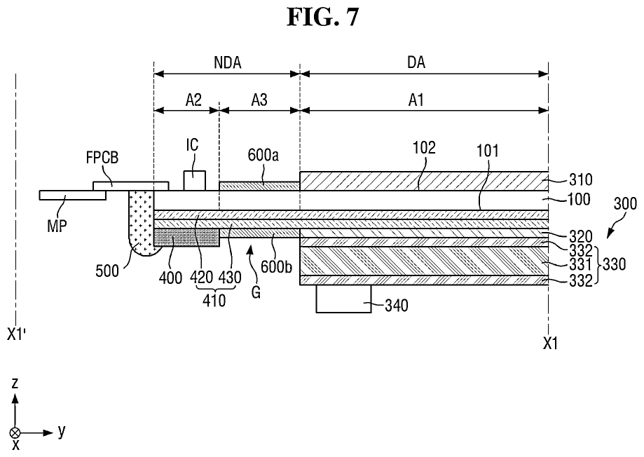

FIG. 7 is a cross-sectional view taken along line X1-X1′ of FIGS. 2 and 3 and particularly a cross-sectional view of the display panel 100 on which a panel bottom cover 300, a support film 400, and a substrate cover layer 500 are located in the first through third areas A1 through A3.

The panel bottom cover 300 is bonded to a bonding layer 410 in the first area A1 and is laterally spaced apart from the support film 400. The panel bottom cover 300 may be bonded to the lower surface 101 of the display panel 100 by the bonding layer 410 and may support the display panel 100.

A polarizer 310 is located on the panel bottom cover 300 with the display panel 100 interposed between them. The polarizer 310 may increase a contrast ratio of images on the display panel 100 by expressing true black, and the polarizer 310 is located on an upper surface 102 of the display panel 100 to improve visibility of displayed images.

The panel bottom cover 300 may include an adhesive member 320 attached to the bonding layer 410, a heat dissipation member 330 for efficiently dissipating the heat of the display panel 100, and a bending adhesive member 340 for controlling and fixing a bent configuration of the display panel 100 when the display panel 100 is bent.

The adhesive member 320 is interposed between the bonding layer 410 and the heat dissipation member 330 to attach the panel bottom cover 300 to the bonding layer 410. The adhesive member 320 may be an adhesive layer made of a pressure sensitive adhesive (PSA) and may attach the panel bottom cover 300 to the bonding layer 410. For example, the adhesive member 320 may include, but is not limited to, an acrylic or silicone adhesive. The adhesive member 320 may be formed as a pressure sensitive adhesive layer that further includes a light absorbing material such as black pigment or black dye to absorb light incident from the outside.

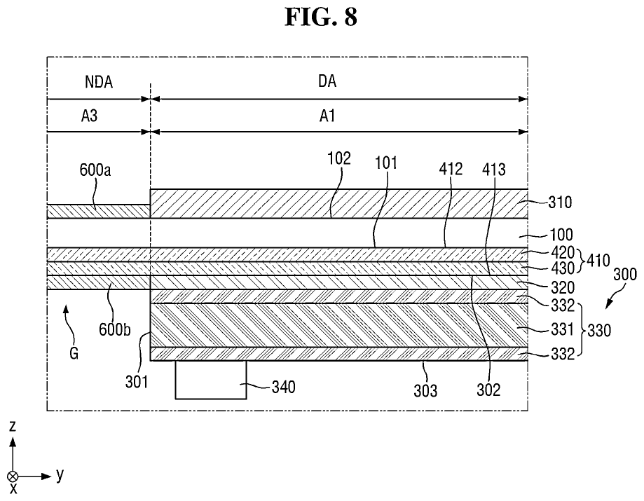

The heat dissipation member 330 may be bonded by the adhesive member 320 and may include a metal layer 331 and a plating layer 332 formed on at least one of upper and lower surfaces of the metal layer 331. The metal layer 331 may be, but is not limited to, a thin film made of one or more metals selected from copper, nickel, ferrite, and silver with excellent thermal conductivity. The plating layer 332 may be made of metal that is the same or different from the metal forming the metal layer 331. Although FIG. 8 shows the plating layer 332 formed on both the upper and lower surfaces of the metal layer 331, the plating layer 332 may alternatively be formed on only one surface of the metal layer 331.

The heat dissipation member 330 may also be, but is not limited to, a composite layer including, for example, a first layer containing graphite or carbon nanotubes and a second layer made of a metal thin film such as copper, nickel, ferrite or silver which can shield electromagnetic waves and has excellent thermal conductivity.

The bending adhesive member 340 may limit and fix the bent configuration of the display panel 100 when the display panel 100 is bent. The position of the display panel 100 may be fixed by attaching the support film 400 to the bending adhesive member 340 in the bent configuration of the display panel 100. The bending adhesive member 340 may include, but is not limited to, an acrylic or silicone adhesive.

The panel bottom cover 300 may further include a buffer member (not illustrated). The buffer member may be located on the heat dissipation member 330 and the bending adhesive member 340. The buffer member (not illustrated) may be formed as a cushion layer to support the display panel 100 and may absorb external shock to prevent damage to the display panel 100. For example, the buffer member (not illustrated) may be made of polymer resin such as polyurethane, polycarbonate, polypropylene or polyethylene or may be made of an elastic material such as a sponge formed by foam molding rubber, a urethane-based material, or an acrylic-based material.

The support film 400 is spaced apart from the heat dissipation member 330 of the panel bottom cover 300. In particular, the gap G is in the third area A3 and provides a space between the support film 400 of the second area A2 and the heat dissipation member 330 of the first area A1.

FIG. 7 shows a flat configuration of the display panel 100 where the support film 400 is spaced apart in a horizontal direction from the heat dissipation member 330 and the gap G is between the support film 400 and the heat dissipation member 330. The support film 400 and the heat dissipation member 330 spaced apart from each other may be parallel to each other.

The support film 400 is bonded to the lower surface 101 of the display panel 100 by the bonding layer 410 in the second area A2 at a position corresponding to and overlapping the driving chip IC in a vertical direction.

The support film 400 may be made of at least one of, for example, polyethylene terephthalate (PET), polycarbonate (PC), and polymethyl methacrylate (PMMA). The support film 400 may particularly be made of polyethylene terephthalate (PET), but the present disclosure is not limited thereto.

The support film 400 may be made of a film with high tensile modulus or high light transmittance.

When the support film 400 is made of a film with a high tensile modulus, the support film 400 can support the flexible display panel 100, protect the lower surface 101 of the display panel 100, and prevent the formation of cracks during a process of mounting the driving chip IC on the display panel 100.

When the driving chip IC is mounted on the second area A2 of the display panel 100, pressure may be applied to the second area A2. Here, since the support film 400 disposed on the lower surface 101 of the display panel 100 corresponding to the second area A2 has a high tensile modulus, it is possible to prevent the pressure applied during the process of mounting the driving chip IC from forming cracks in the wirings in the non-display area NDA.

When the support film 400 is made of a film with high transmittance, the light transmittance of the support film 400 may be, but is not limited to, about 80% or more.

When the support film 400 is made of a film with high transmittance, the driving chip IC may be mounted on the display panel 100 by high-pressure bonding in the second area A2 to which the support film 400 is bonded. Whether the driving chip IC has been properly mounted can be inspected using an optical microscope or the like to view the bond through the support film 400. Here, since the light transmittance of the support film 400 located in the second area A2 where the driving chip IC is mounted is high, the mounted state of the driving chip IC can be inspected more easily. Accordingly, the problem of defects caused by compression of the driving chip IC can be detected or solved.

In the case of the first area A1 spaced apart from the second area A2, the display panel 100 may be folded along the folding axis FX. Here, if the support film 400 were disposed in the first area A1 that is foldable, the support film 400 could change the position of a neutral plane when the display panel 100 is bent or folded. However, since the support film 400 is not disposed in the first area A1 in the embodiment of FIG. 7, the support film 400 does not change the position of the neutral plane in the first area A1.

If the support film 400 was located in the first area A1, the overall thickness of the display device 1 may increase because stacked structures increase in the first area A1, including in the display area DA. However, according to the present disclosure, the support film 400 is disposed in the second area A2, which is the non-display area NDA, and is not disposed in the first area A1, which is the display area DA. Therefore, the stacked structures can be reduced in the first area A1 and the display area DA, thereby reducing the overall thickness of the display device 1.

In addition, since the support film 400 is not disposed in the first area A1, the stacked structures can be reduced in the first area A1 and the display area DA, thereby reducing manufacturing costs.

According to the present disclosure, the support film 400 is not disposed in the first area A1 but is located on the lower surface 101 of the display panel 100 at a position corresponding to the driving chip IC of the second area A2. Therefore, the display panel 100 can be protected in the second area A2, and the problems of cracks and driving chip defects can be solved.

The bonding layer 410 may be formed on the entire lower surface 101 of the display panel 100 in all areas A1 through A3 including the first area A1, the second area A2 and the third area A3 along the horizontal direction. The bonding layer 410 bonds the panel bottom cover 300 to the lower surface 101 of the display panel 100 in the first area A1 and bonds the support film 400 to the lower surface 101 of the display panel 100 in the second area A2. In addition, the bonding layer 410 may bond a lower protective layer 600b, which will be described later, to the lower surface 101 of the display panel 100 in the third area A3.

The panel bottom cover 300, the support film 400, and the lower protective layer 600b in different areas A1 through A3 can all be bonded to the lower surface 101 of the display panel 100 using one bonding layer 410 since the bonding layer 410 is formed on the entire lower surface 101 of the display panel 100. That is, since only one bonding layer 410 is provided, the number of components for bonding the above elements can be reduced, thereby reducing the thickness and manufacturing costs of a display device. In addition, since the process of bonding each of the above elements is simplified, the efficiency of a manufacturing process can be improved.

The bonding layer 410 may have adhesiveness capable of attaching the support film 400 and may have a high storage modulus.

The bonding layer 410 in the embodiment of FIG. 7 includes a first adhesive layer 420 located on the lower surface 101 of the display panel 100 and a second adhesive layer 430 located on a lower surface of the first adhesive layer 420. The first adhesive layer 420 is interposed between the lower surface 101 of the display panel 100 and the second adhesive layer 430 and is bonded to the lower surface 101 of the display panel 100.

The first adhesive layer 420 may be a fixed adhesive layer 420 whose adhesive strength is maintained without being changed by light irradiation or an optical coupling adhesive layer 420 whose adhesive strength is increased by light irradiation. When the first adhesive layer 420 is an optical coupling adhesive layer 420, the adhesive strength of the first adhesive layer 420 may be 100 gf/inch or less before light irradiation and may be 250 gf/inch or more after light irradiation.

The second adhesive layer 430 is interposed between the first adhesive layer 420 and the panel bottom cover 300 in the first area A1 and between the first adhesive layer 420 and the support film 400 in the second area A2. The second adhesive layer 430 is interposed between the first adhesive layer 420 and the lower protective layer 600b in the third area A3.

The second adhesive layer 430 may be a light-peelable adhesive layer 430 whose adhesive strength is reduced by light irradiation. When the second adhesive layer 430 is a light-peelable adhesive layer 430, the adhesive strength of the second adhesive layer 430 may be 250 gf/inch or more before light irradiation and may decrease to 50 gf/inch or less after light irradiation. In this case, the second adhesive layer 430 can be easily peeled off during the manufacturing process. Accordingly, process convenience can be improved, and a defect rate can be reduced because the removed second adhesive layer 430 leaves no residue or damage on a peeled surface.

The second adhesive layer 430 may include, for example, one or more of polyester acrylate resin, unsaturated polyester resin, polyurethane acrylate resin, epoxy acrylate resin, epoxy resin, polyether acrylate resin, and polythiol acrylate resin. The second adhesive layer 430 may most preferably include an ultraviolet (UV)-peelable adhesive, but the present disclosure is not limited thereto.

When the storage modulus of the bonding layer 410 is high, it is possible to prevent cracks from being formed by pressure during the process of mounting the driving chip IC because the bonding layer 410 having a high storage modulus is located where pressure is applied in the second area A2 of the display panel 100.

The substrate cover layer 500 may be disposed on a lower surface of the flexible printed circuit board FPCB at a position in contact with the bonding layer 410 and the support film 400 of the second area A2 and the display panel 100. The substrate cover layer 500 may be formed using various forms of organic layer and may include, for example, one or more of acrylic resin and urethane resin. However, the present disclosure is not limited thereto.

The lower protective layer 600b may be disposed on the bonding layer 410 at a position corresponding to the third area A3. An upper protective layer 600a may be located on the upper surface 102 of the display panel 100 to overlap the lower protective layer 600b. In addition, each of the protective layers 600a and 600b may be disposed at a position between the first area A1 and the second area A2.

The upper protective layer 600a is located between the polarizer 310 in the first area A1 and the driving chip IC in the second area A2 along the horizontal direction and is disposed on the upper surface 102 of the display panel 100.

The upper protective layer 600a may act as a neutral plane adjustment layer on the non-display area NDA of the display panel 100.

The neutral plane adjustment layer 600a may overlap the bendable third area A3 of the non-display area NDA of the display panel 100. The neutral plane adjustment layer 600a may be formed only in the third area A3. Alternatively, a portion of the neutral plane adjustment layer 600a may also be formed to overlap the first area A1 and/or the second area A2.

The neutral plane adjustment layer 600a may prevent the formation of cracks in the wirings within the driving layer 120 by relieving the stress applied to the driving layer 120 in the bendable third area A3. More specifically, the driving layer 120 may include wirings passing through the non-display area NDA of the first area A1 and the third area A3, and elements in the driving layer 120 may be electrically connected to the driving chip IC through the wirings. The neutral plane adjustment layer 600a may adjust the position of the neutral plane to prevent tensile stress from acting on the wirings located in the third area A3. Here, the neutral plane refers to a plane on which neither compressive stress nor tensile stress acts when the third area A3 of the display panel 100 is bent. For example, when the third area A3 is bent, compressive stress acts on the inside of a bending curvature, and tensile stress acts on the outside. Therefore, from the inside toward the outside of the curvature, the direction of stress gradually changes from a compression direction to a tension direction. At a certain critical point, there is a transition point where neither compressive stress nor tensile stress acts, and this point becomes the neutral plane. The neutral plane adjustment layer 600a can adjust the neutral plane so that compressive stress acts on the wirings in the driving layer 120, thereby reducing the risk of crack formation.

The neutral plane adjustment layer 600a may be made of an organic material. The organic material may be, for example, a photosensitive organic material. For example, the neutral plane adjustment layer 600a may include one or more of acrylic resin and urethane resin.

Although the neutral plane adjustment layer 600a is spaced apart from the driving chip IC in the drawing, the present disclosure is not limited thereto. The neutral plane adjustment layer 600a may also extend to an area where the driving chip IC is disposed and may cover a portion of the driving chip IC. In this case, the coupling reliability between the driving chip IC and the display panel 100 can be improved.

The lower protective layer 600b is located between the adhesive member 320 of the first area A1 and the support film 400 of the second area A2 and is bonded to the bonding layer 410 located in the third area A3. Specifically, the lower protective layer 600b may be bonded to the light-peelable adhesive layer 430, which is the second adhesive layer 430 of the bonding layer 410.

The lower protective layer 600b may be made of the same material as the upper protective layer 600a and may include, for example, one or more of acrylic resin and urethane resin. The lower protective layer 600b may also be made of a different material from the upper protective layer 600a.

The lower protective layer 600b may be bonded to the light-peelable adhesive layer 430, which is the second adhesive layer 430 of the bonding layer 410, in the third area A3 and may support the lower surface 101 of the display panel 100 and protect the lower surface 101 of the display panel 100. Although both the upper and lower protective layers 600a and 600b are shown in the illustrated embodiment, the present disclosure is not limited thereto, and one or both of the upper and lower protective layers 600a and 600b may be omitted in other embodiments.

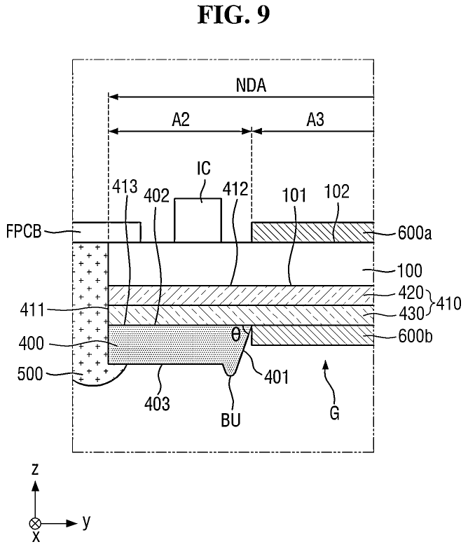

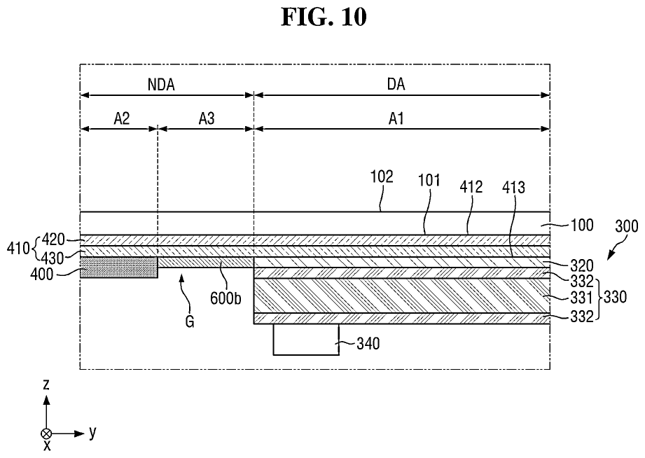

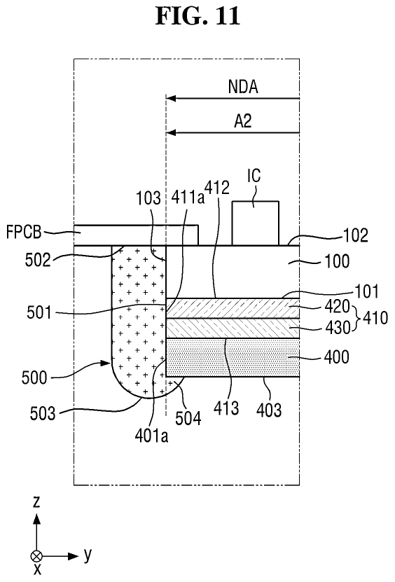

FIG. 8 is an enlarged view focused on the first area A1 of FIG. 7. FIG. 9 is an enlarged view of a boundary area between the second area A2 and the third area A3 of FIG. 7. FIG. 10 is an enlarged view of the display panel 100, the bonding layer 410, the support film 400, and the panel bottom cover 300 in the first through third areas A1 through A3 of FIG. 7. FIG. 11 is an enlarged view of the second area A2 and a flexible printed circuit board bonding area of FIG. 7.

The panel bottom cover 300 of FIG. 8 may include an inner or side surface 301 adjacent to the gap G, an upper surface 302 facing a lower surface 413 of the bonding layer 410, and a lower surface 303 opposite the upper surface 302. The upper surface 302 of the panel bottom cover 300 may contact the light-peelable adhesive layer 430 of the bonding layer 410.

An angle formed by the inner surface 301 of the panel bottom cover 300 and the lower surface 413 of the bonding layer 410 may be a right angle. In this case, the panel bottom cover 300 may have a rectangular cross-sectional shape as illustrated in FIG. 8. However, the shape of the panel bottom cover 300 is not limited to the rectangular shape.

The support film 400 as shown in FIG. 9 includes an inner or side surface 401 adjacent to the gap G, an upper surface 402 facing the lower surface 413 of the bonding layer 410, and a lower surface 403 opposite the upper surface 402. The upper surface 402 of the support film 400 may contact the light-peelable adhesive layer 430 of the bonding layer 410.

An inclination angle θ formed by the inner surface 401 of the support film 400 exposed to the gap G in the third area A3 and the lower surface 413 of the bonding layer 410 may be an acute angle. For example, the inclination angle θ may be between 0 and 70 degrees. However, the present disclosure is not limited thereto. For example, the inclination angle θ in FIG. 9 may be smaller than the angle formed by the inner surface 301 of the panel bottom cover 300 and the lower surface 413 of the bonding layer 410, but the present disclosure is not limited thereto.

The support film 400 may further include a burr pattern BU protruding downward from the lower surface 403 along the inner surface 401 adjacent to the gap G. The burr pattern BU of the support film 400 may be formed in a process of irradiating laser light on the support film 400 during the manufacturing process. The burr pattern BU may be formed as the thermal energy of the laser light melts a portion of the support film 400. The burr pattern BU of the support film 400 may protrude downward from the lower surface 403 of the support film 400. The burr pattern BU may extend in the same direction as the gap G, for example, along the first direction x.

The bonding layer 410 of FIG. 10 may include an upper surface 412 in contact with the lower surface 101 of the display panel 100 and the lower surface 413 opposite the upper surface 412.

The panel bottom cover 300 of the first area A1, the support film 400 of the second area A2, and the lower protective layer 600b of the third area A3 may be disposed on the lower surface 413 of the bonding layer 410. That is, the adhesive member 320, the lower protective layer 600b, and the support film 400 may be bonded together to the light-peelable adhesive layer 430 which is the second adhesive layer 430 of the bonding layer 410.

The substrate cover layer 500 of FIG. 11 may include a cover layer side surface 501, a cover layer upper surface 502, and a cover layer lower surface 503. The cover layer side surface 501 contacts respective side surfaces 401a, 411a, and 103 of the bonding layer 410, the support film 400, and the display panel 100. The cover layer upper surface 502 contacts the lower surface of the flexible printed circuit board FPCB, and the cover layer lower surface 503 is opposite the cover layer upper surface 502.

The cover layer upper surface 502 may support the flexible printed circuit board FPCB from below the flexible printed circuit board FPCB, and the cover layer side surface 501 may support and protect the respective side surfaces 401a 411a, and 103 of the bonding layer 410, the support film 400, and the display panel 100.

The substrate cover layer 500 may further include a cover portion 504 extending from the cover layer lower surface 503 toward the side surface 401a of the support film 400. The cover portion 504 may cover, that is, seal a portion of the lower surface 403 of the support film 400. Therefore, it is possible to prevent the penetration of moisture into the flexible printed circuit board FPCB and the driving chip IC connected to the flexible printed circuit board FPCB, thereby preventing corrosion due to the moisture.

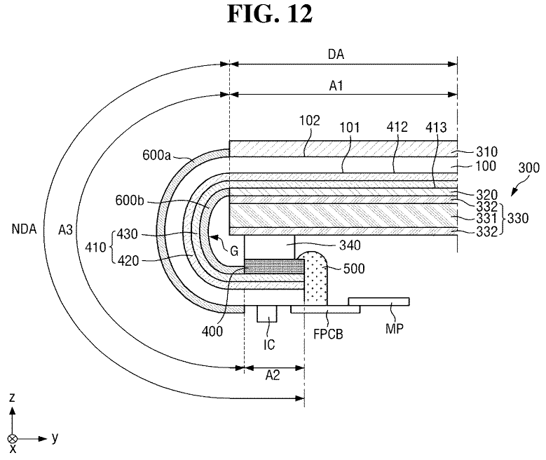

FIG. 12 is a cross-sectional view of the display device 1 of FIG. 7 in a bent state, more specifically, a cross-sectional view of the non-display area NDA of the display device 1 in the bent state.

Referring to FIG. 12, the display panel 100 of the display device 1 may be bent about the bending axis BX (see FIG. 1) to place area A2 of the display panel 100 under area A1 of the display panel 100. The bending axis BX (see FIG. 1) extends along the first direction x in the third area A3. Since the gap G overlapping the third area A3 is between the panel bottom cover 300 and the support film 400, the area A3 of the display panel 100 can be bent more easily. Here, bending brings the support film 400 into contact with the bending adhesive member 340 of the panel bottom cover 300, so that the bent configuration of the display panel 100 may fixed by the bending adhesive member 340.

Depending on the position at which the support film 400 is attached to the bending adhesive member 340, the alignment state can be changed. For example, the display panel 100 and the support film 400 may have respective edges that are aligned in a row in the vertical direction. Alternatively, as illustrated in FIG. 12, moving the support film 400 to the right and fixing the support film 400 in that position may cause the support film 400 to form a step on the display panel 100.

Since a part of the non-display area NDA of the display panel 100 is bent, the area of the non-display area NDA of the display device 1 which is visible from the top of the display device 1 be reduced, and the bezel width around the display area DA of the display device 1 can be reduced. In addition, the neutral plane adjustment layer 600a overlapping the third area A3 on the display panel 100 may be chosen to prevent the formation of cracks in the wirings of the display panel 100 in the third area A3 and to thereby improve the reliability of the display device 1.

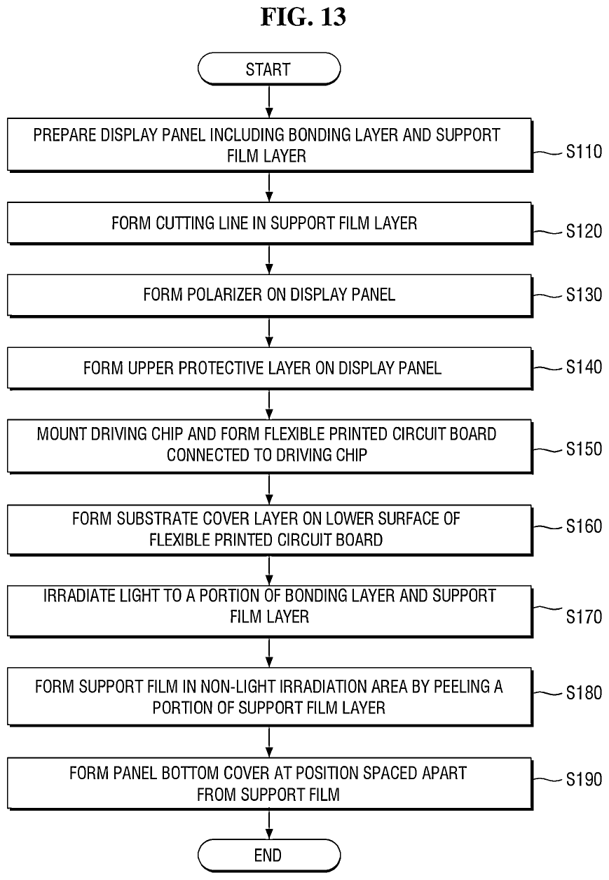

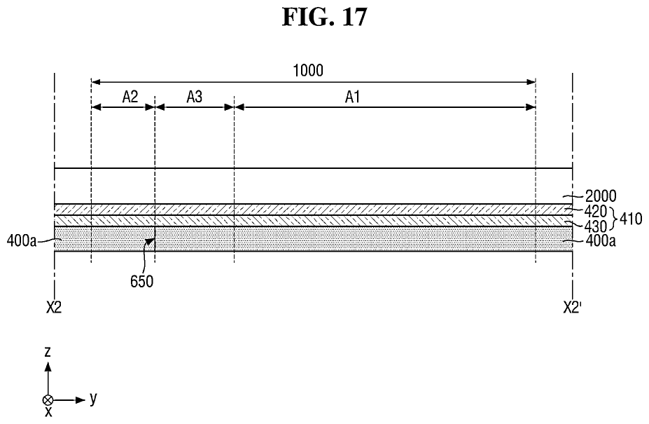

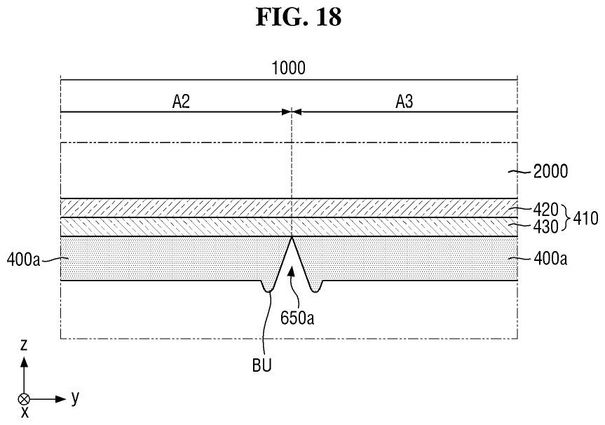

A method of manufacturing the display device 1 according to the present disclosure will now be described with reference to FIGS. 13 through 21.

The method of manufacturing the display device 1 according to the present disclosure may include the operations shown in FIG. 13.

First, a display panel 100 may be prepared (operation S110 in FIG. 13). The display panel 100 may particularly include the bonding layer 410 and the support film 400.

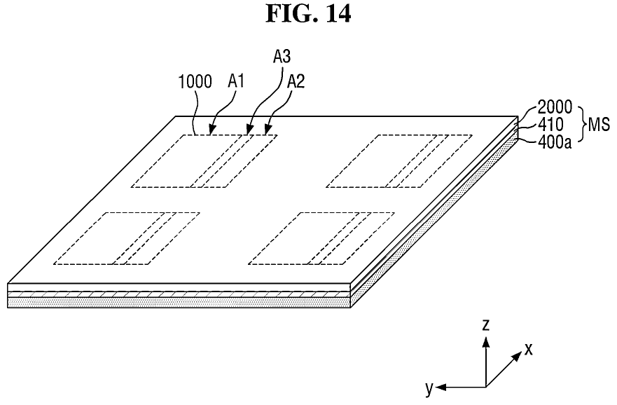

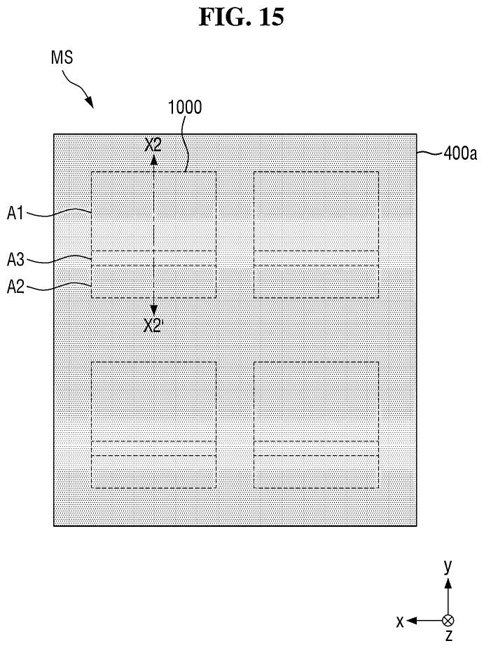

Referring to FIGS. 14 and 15, a mother substrate 2000 may be prepared, a bonding layer 410 may be formed on a lower surface of the mother substrate 2000, and a support film layer 400a in a raw state may be bonded to the bonding layer 410 to produce a mother substrate structure MS.

The mother substrate structure MS may include a plurality of display cells 1000 and a dummy area other than the display cells 1000.

Each display cell 1000 may be separated from the mother substrate 2000 to form the display panel 100. Each display cell 1000 may include a first area A1, a second area A2, and a third area A3. The cross-sectional stacked structure of each display cell 1000 may be the same as that of the display panel 100 illustrated in FIG. 5 or 6.

The dummy area may be a portion other than the display cells 1000 and an area to be removed through a laser cutting process.

After the mother substrate structure MS is manufactured, a cutting process may be performed by irradiating laser light onto the mother substrate structure MS. In the cutting process, the display cells 1000 may be separated by removing the dummy area from the mother substrate structure MS. Each of the separated display cells 1000 may be prepared as the display panel 100 including the bonding layer 410 and the support film layer 400a.

Second, a cutting line 650 may be formed (operation S120 in FIG. 13) in the support film layer 400a of each display panel 100. Here, the cutting line 650 may be formed after the display cells 1000 are separated from the mother substrate structure MS, or the display cells 1000 may be separated from the mother substrate structure MS after the cutting line 650 is formed.

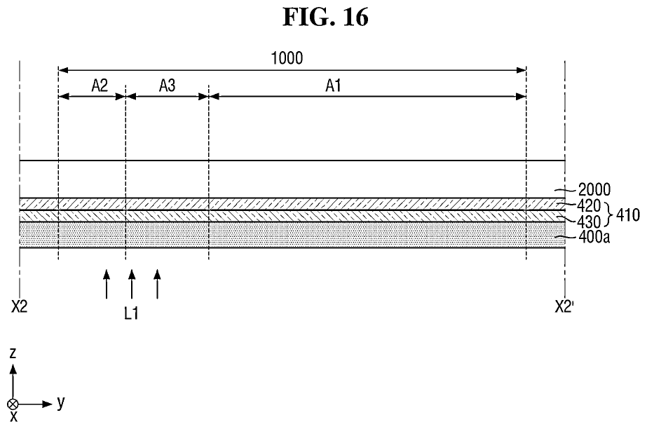

Referring to FIGS. 16 through 18, the cutting line 650 may be formed in the support film layer 400a by cutting the support film layer 400a by irradiating laser light L1 from below the support film layer 400a. The cutting line 650 may particularly be formed in the support film layer 400a by irradiating laser light along the first direction x which is the short-side direction of the display panel 100. The cutting line 650 may be a boundary line between the second area A2 and the third area A3.

A cutting line area 650a is an area formed around the cutting line 650 in the process of irradiating the support film layer 400a with the laser light L1. A burr pattern BU may be formed on a cut surface of the support film layer 400a in the cutting line area 650a and may be formed as the thermal energy of the laser light L1 melts a portion of the support film layer 400a. Here, the laser light L1 may be, but is not limited to, CO₂ laser light with high energy efficiency. The burr pattern BU may extend in the same direction as the cutting line 650 along the boundary between the third area A3 and the second area A2.

Third, a polarizer 310 may be formed (operation S130 in FIG. 13). The polarizer 310 may particularly be formed on an upper surface 102 of the display panel 100 in the first area A1.

Fourth, an upper protective layer 600a may be formed (operation S140 in FIG. 13). The upper protective layer 600a may particularly be formed on the upper surface 102 of the display panel 100 in the third area A3. Although only the upper protective layer 600a is formed in the example process of FIG. 13, an operation of forming a lower protective layer 600b on the bonding layer 410 may be further included.

Fifth, a driving chip IC and a flexible printed circuit board FPCB may be formed and mounted on the display panel 100 (operation S150 in FIG. 13). The driving chip IC may be mounted on the upper surface 102 of the display panel 100 in the second area A2, and an end of the flexible printed circuit board FPCB may be coupled to the display panel 100 in the second area A2.

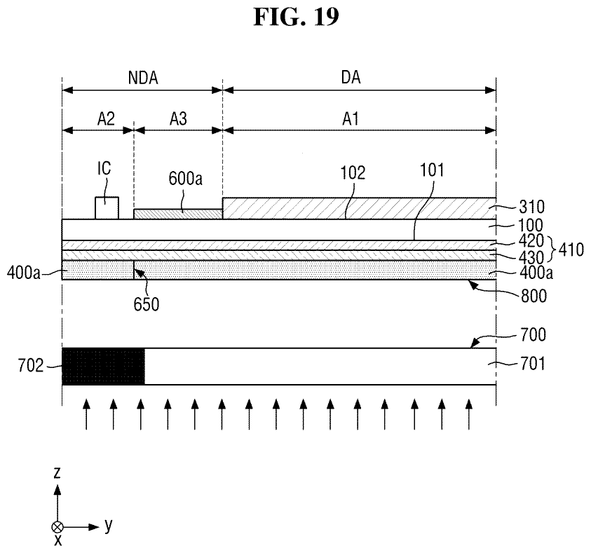

Sixth, a substrate cover layer 500 may be formed (operation S160 in FIG. 13). The substrate cover layer 500 may be formed on a lower surface of the flexible printed circuit board FPCB and adjacent to an edge of the display panel 100. Here, the flexible printed circuit board FPCB and the substrate cover layer 500 may be the same as those illustrated in FIG. 7 and thus are not illustrated in FIGS. 19 through 21.

Seventh, light may be irradiated (operation S170 in FIG. 13). Referring to FIG. 19, a mask 700 that can selectively pass light may be placed under the support film layer 400a having the cutting line 650, and then light may be irradiated. A portion of the bonding layer 410 and the support film layer 400a located in the first and third areas A1 and A3 may be a target light irradiation area, and light may be irradiated to the light irradiation area through a light transmitting portion 701 of the mask 700 onto the target light irradiation area. A portion of the bonding layer 410 and the support film layer 400a located in the second area A2 may be a non-light irradiation area, and a light blocking portion 702 of the mask 700 may prevent light from irradiating the non-light irradiation area. Here, the light irradiation may be irradiation of UV laser light.

After UV light is irradiated as described above, the adhesive strength of a light-peelable adhesive layer 430, which is a second adhesive layer 430 of the bonding layer 410, may be weakened in the first and third areas A1 and A3 irradiated with the light. On the other hand, the adhesive strength of the light-peelable adhesive layer 430 of the bonding layer 410 may be maintained in the second area A2 not irradiated with the light. For example, the adhesive strength of the light-peelable adhesive layer 430 may be 250 gf/inch or more before UV irradiation but may decrease to 50 gf/inch or less after the UV irradiation. Therefore, the support film layer 400a in the light irradiation area can be easily removed. Accordingly, the support film layer 400a may be removed from a peeling area 800 which is a light irradiation area, so that the removed portion of the support film layer 400a does not cause defects or leave damage to a peeled surface. Thereby, a defect rate may be reduced. In addition, issues such as tearing during the peeling process can be suppressed. The adhesive strength may also be reduced to 20 gf/inch or less, but the present disclosure is not limited thereto.

Here, when a first adhesive layer 420 of the bonding layer 410 is a fixed adhesive layer 420, UV light irradiation does not change the adhesive strength of the first adhesive layer 420. When the first adhesive layer 420 is an optical coupling adhesive layer 420, the adhesive strength of the first adhesive layer 420 may be 100 gf/inch or less before light irradiation and may increase to 250 gf/inch or more after the light irradiation. Therefore, strong adhesive strength can be provided to maintain the bonded state, and the detachment of the bonding layer 410 can be prevented.

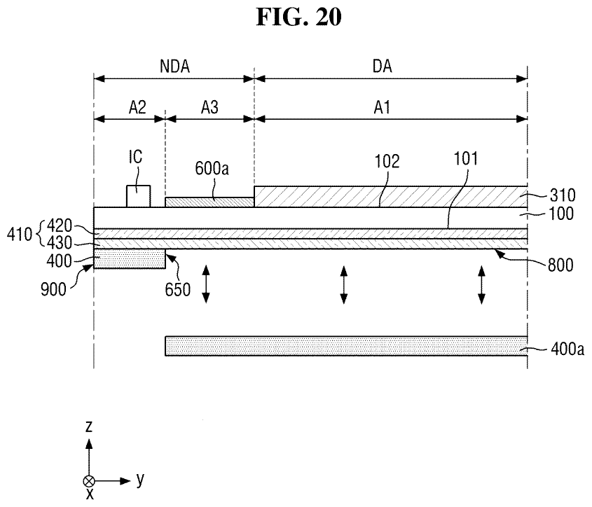

Eighth, the support film 400 may be formed (operation S180) in the non-light irradiation area. Referring to FIG. 20, portions of the support film layer 400a located in the first and third areas A1 and A3, which are light irradiation areas, may be removed by peeling them off along the cutting line 650. Since the second adhesive layer 430 located in the first and third areas A1 and A3, which are light irradiation areas, are formed as a light-peelable adhesive layer 430, its adhesive strength may be reduced by light irradiation. Therefore, the support film layer 400a in the first and third areas A1 and A3 can be easily peeled and removed. The area from which the support film layer 400a has been removed is formed as the peeling area 800.

The bonding layer 410 located in the second area A2, which is a non-light irradiation area, maintains or has a high adhesive strength because the non-light irradiation area is not irradiated with light. Therefore, the bonding layer 410 and the support film layer 400a located in the second area A2 can be kept bonded to each other. Here, the area where the bonding layer 410 and the support film layer 400a are kept bonded to each other may be formed as a bonding area 900, and the support film layer 400a of the second area A2 which has not been peeled off may be formed as the support film 400.

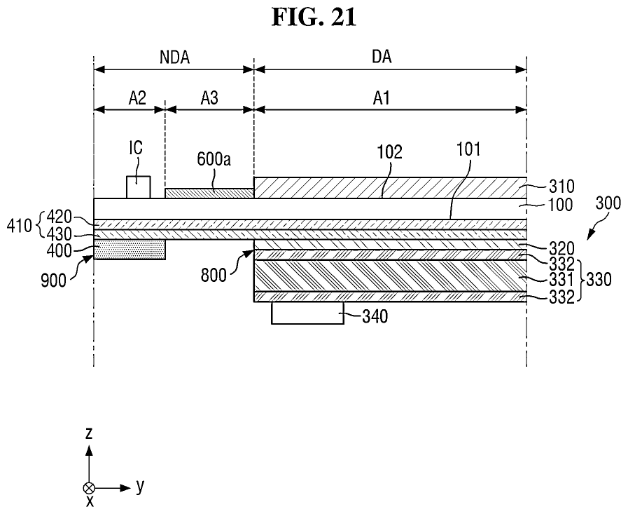

Ninth, a panel bottom cover 300 may be formed (operation S190). Referring to FIG. 21, in the panel bottom cover 300, an adhesive member 320 is bonded to the second adhesive layer 430 of the bonding layer 410 at a position corresponding to the first area A1 within the peeling area 800, and the adhesive member 320 is spaced apart from the support film 400 of the bonding area 900.

Finally, the support film 400 of the second area A2 and the panel bottom cover 300 of the first area A1 share the bonding layer 410 formed over the first through third areas A1 through A3. The support film 400 of the second area A2 and the panel bottom cover 300 of the first area A1 may be kept bonded to a lower surface 101 of the display panel 100 by the bonding layer 410 with a gap G in the third area A3 between them. Through these processes, the display device 1 according to the present disclosure can be manufactured.

In this way, according to the manufacturing method of the present disclosure, manufacturing cost of the display device 1 can be reduced, and the display device 1 with a reduced thickness can be provided.

In concluding the detailed description, those skilled in the art will appreciate that many variations and modifications can be made to the example embodiments without substantially departing from the principles of the present disclosure. Therefore, the example embodiments are used in a generic and descriptive sense only and not for purposes of limitation. Each component specifically shown in the embodiments may be modified for specific applications, and such modifications and differences related to the application should be construed as being included in the scope defined in the appended claims.

What is claimed is:

1. A display device comprising:
a display panel comprising a first area comprising a display area, a second area spaced apart from the first area, and a bendable third area located between the first area and the second area;
a bonding layer disposed in the first area, the second area, and the third area of the display panel, the bonding layer being located on a lower surface of the display panel;
a panel bottom cover disposed in the first area of the display panel and bonded to the bonding layer; and
a support film disposed in the second area of the display panel and bonded to the bonding layer,
wherein a gap which separates the panel bottom cover and the support film from each other is in the third area.

2. The display device of claim 1, wherein the bonding layer comprises a fixed adhesive layer located on the lower surface of the display panel and a light-peelable adhesive layer located on a lower surface of the fixed adhesive layer.

3. The display device of claim 1, wherein the bonding layer comprises an optical coupling adhesive layer located on the lower surface of the display panel and a light-peelable adhesive layer located on a lower surface of the optical coupling adhesive layer.

4. The display device of claim 3, wherein the adhesive strength of the optical coupling adhesive layer after light irradiation is 250 gf/inch or more, and the adhesive strength of the light-peelable adhesive layer after the light irradiation is 50 gf/inch or less.

5. The display device of claim 3, further comprising a protective layer formed on a lower surface of the light-peelable adhesive layer in the third area.

6. The display device of claim 1, wherein the panel bottom cover comprises:
an adhesive member bonded to the bonding layer in the first area;
a heat dissipation member bonded to the adhesive member and dissipating heat of the display panel; and
a bending adhesive member bonded to the heat dissipation member, the bending adhesive member fixing the display panel in a bent configuration when the display panel is bent.

7. The display device of claim 1, wherein the support film further comprises a burr pattern protruding downward from a lower surface of the support film along an inner surface adjacent to the gap.

8. The display device of claim 1, wherein an angle formed by an inner surface of the support film adjacent to the third area and a lower surface of the bonding layer is 70 degrees or less.

9. The display device of claim 1, further comprising a driving chip disposed in the second area of the display panel and located on an upper surface facing the lower surface of the display panel.

10. The display device of claim 9, further comprising:
a flexible printed circuit board electrically connected to the driving chip; and
a substrate cover layer formed on a lower surface of the flexible printed circuit board.

11. The display device of claim 10, wherein an end of the flexible printed circuit board is bonded to an edge of the display panel in the second area, and the substrate cover layer is located on the lower surface of the flexible printed circuit board at the edge of the display panel and contacts a side surface of the display panel, a side surface of the bonding layer, and a side surface of the support film in the second area.

12. The display device of claim 11, wherein the substrate cover layer further comprises a cover portion extending from a lower surface of the substrate cover layer toward the side surface of the support film that contacts the substrate cover layer and covering a portion of a lower area of the support film.

13. A display device comprising:
a display panel comprising a first area comprising a display area, a second area spaced apart from the first area, and a bendable third area located between the first area and the second area;
a bonding layer disposed in the first area, the second area and the third area of the display panel, the bonding layer being located on a lower surface of the display panel;
a support film disposed in the second area of the display panel and bonded to the bonding layer;
a flexible printed circuit board having an end bonded to a distal area of the display panel in the second area; and
a substrate cover layer formed on a lower surface of the flexible printed circuit board.

14. The display device of claim 13, wherein the bonding layer comprises a first adhesive layer located on the lower surface of the display panel and a second adhesive layer located on a lower surface of the first adhesive layer, and the second adhesive layer is a light-peelable adhesive layer.

15. The display device of claim 14, further comprising a protective layer formed on a lower surface of the light-peelable adhesive layer in the third area.

16. The display device of claim 13, wherein the substrate cover layer further comprises a cover portion extending from a lower surface of the substrate cover layer toward a side surface of the support film which contacts the substrate cover layer and covering a portion of a lower area of the support film.

17. The display device of claim 13, further comprising a panel bottom cover disposed in the first area of the display panel and bonded to the bonding layer.

18. The display device of claim 17, wherein the panel bottom cover comprises an adhesive member bonded to the bonding layer in the first area, a heat dissipation member bonded to the adhesive member and dissipating heat of the display panel, and a bending adhesive member bonded to the heat dissipation member and fixing the display panel in a bent configuration when the display panel is bent, the third area comprises a gap which is a space formed between the support film and the heat dissipation member, and the support film further comprises a burr pattern protruding downward from the lower surface of the support film along an inner surface adjacent to the gap.

19. The display device of claim 18, further comprising a driving chip disposed in the second area of the display panel and located on an upper surface of the display panel.

20. A method of manufacturing a display device having a display panel which comprises a first area comprising a display area, a second area spaced apart from the first area, and a bendable third area comprising a gap between the first area and the second area, the method comprising:
preparing the display panel which comprises a bonding layer formed on an entire lower surface of the display panel in the first through third areas and a support film layer bonded to the bonding layer;
forming a cutting line in the support film layer as a boundary between the second area and the third area;
selectively irradiating light onto the first and third areas of the support film layer in which the cutting line is formed;
forming a support film in the second area by peeling by removing the support film layer in the first and third areas irradiated with the light; and
forming a panel bottom cover on the bonding layer of the first area at a position spaced apart from the support film with the gap interposed therebetween.
